(19) United States
(12) Patent Application Publication
(10) Pub. No.: US 2025/0208194 A1
(43) Pub. Date: Jun. 26, 2025

(54) CURRENT-BASED BUILT-IN SELF-TEST FOR CIRCUIT COMPONENTS ARRANGED IN VARIED CONFIGURATIONS

(71) Applicant: SEMICONDUCTOR COMPONENTS INDUSTRIES, LLC, Scottsdale, AZ (US)

(72) Inventors: Petr KAMENICKY, Brno (CZ); Jiri KUTEJ, Brno (CZ); Pavel HORSKY, Brno (CZ)

(73) Assignee: SEMICONDUCTOR COMPONENTS INDUSTRIES, LLC, Scottsdale, AZ (US)

(21) Appl. No.: 18/392,317

(22) Filed: Dec. 21, 2023

(51) Int. Cl. G01R 31/28

(52) U.S. Cl. CPC G01R 31/2834

(57) ABSTRACT

A self-testing circuit may transmit a first test vector to a test block of a plurality of test blocks in the self-testing circuit. The first test vector may correspond to a first configuration for a set of components in the test block. The self-testing circuit may measure a first current drawn by the test block when the set of components is in the first configuration. The self-testing circuit may also transmit a second test vector to the test block, the second test vector corresponding to a second configuration for the set of components. The self-testing circuit may measure a second current drawn by the test block when the set of components is in the second configuration. Based on a comparison between the first and second currents, the self-testing circuit may detect a defect in the test block.

### TECHNICAL FIELD

This description relates to methods and systems for built-in self-testing and/or support for efficient production testing of semiconductor products.

### BACKGROUND

Various types of analog and digital circuits are produced by way of intricate and complex semiconductor manufacturing processes. In some examples, these processes produce circuitry with very large numbers of very small electronic components such as transistors, resistors, capacitors, and so forth. Testing to ensure that such large numbers of intricate components included in these complex circuits are functioning properly can present various challenges, particularly on manufacturing lines on which large numbers of products are being produced and in need of thorough testing. External testing equipment in the manufacturing facility can be used to provide input stimulus and to analyze outputs generated based on the input stimulus for each individual circuit (e.g., each die on a wafer, each chip, etc.). However, such equipment may tend to be relatively large, expensive, and slow at performing a thorough suite of tests for each circuit that is produced. As a result, the testing process may add significantly to the cost, complexity, and/or time of manufacturing, and may make it difficult to meet quantity and/or quality (e.g., test coverage) targets for products being manufactured and tested in these ways.

### SUMMARY

Current-based built-in self-testing for circuit components arranged in varied configurations is described herein. In one general aspect, a method for current-based built-in self-test for circuit components arranged in varied configurations may include the following operations. First, a first test vector may be transmitted to a test block of a plurality of test blocks in a self-testing circuit, the first test vector corresponding to a first configuration for a set of components in the test block. Next, a first current drawn by the test block may be measured when the set of components is in the first configuration. A second test vector may then be transmitted to the test block, the second test vector corresponding to a second configuration for the set of components and the second configuration being different from the first configuration. A second current drawn by the test block may be measured when the set of components is in the second configuration. Finally, a defect may be detected in the test block based on a comparison between the first current and the second current.

In some implementations of the method, a variety of additional elements and/or features may be employed. As one example, the method may further include determining, based on the first test vector, a first setting for a set of switches within the test block, the set of switches configured to produce the first configuration for the set of components when the first setting is applied; and determining, based on the second test vector, a second setting for the set of switches, the set of switches configured to produce the second configuration for the set of components when the second setting is applied.

As another example, the test block may include an enable input and may be configured, when the enable input is active, to allow the set of components in the test block to be put in a new configuration. When the enable input is inactive, the test block may be configured to disallow the set of components in the test block from being put in the new configuration (and to put the set of components instead into a configuration associated with normal operation of the test block).

As another example, the method may further include transmitting a third test vector to an additional test block of the plurality of test blocks, the third test vector corresponding to a particular configuration for an additional set of components in the additional test block; and measuring a third current drawn by the additional test block when the additional set of components is in the particular configuration. In this example, the detecting of the defect in the test block may be further based on a comparison between the first current and the third current.

As another example, the method may further include transmitting the first test vector to an additional test block that is included in an additional self-testing circuit manufactured on a same wafer as the self-testing circuit and that corresponds to the test block; and measuring a third current drawn by the additional test block when an additional set of components in the additional test block is in the first configuration. In this example, the detecting of the defect in the test block may be further based on a comparison between the first current and the third current.

As another example, the method may further include converting, using an analog-to-digital converter circuit, the first current to a first value and the second current to a second value; and storing the first value and the second value in a memory. In this example, the comparison between the first current and the second current may then be performed by comparing the first value and the second value as stored in the memory. Also in this example, the comparing of the first value and the second value may include determining a ratio of the first value to the second value; and the detecting of the defect in the test block may include determining that the ratio falls outside a predetermined range. Also in this example, the comparing of the first value and the second value may include determining a difference between the first value and the second value; and the detecting of the defect in the test block may include determining that the difference falls outside a predetermined range.

As another example, the method may include transmitting, to an additional test block of the plurality of test blocks, a third test vector corresponding to a particular configuration for an additional set of components in the additional test block; measuring a third current drawn by the additional test block when the additional set of components is in the particular configuration; and detecting a defect in the additional test block based on the third current without a comparison to another current. In this example, the detecting of the defect in the additional test block may include determining that the third current indicates a short condition or a disconnect condition in the additional test block.

As another example, the set of components may include a resistor component implemented as a first resistor and a second resistor that are configured to be in series during operation of the test block and to be on separate current paths for the first configuration and the second configuration. In this example, the first current drawn by the test block may be associated with a first measured value for the first resistor, the second current drawn by the test block may be associated with a second measured value for the second resistor, and the detecting of the defect in the test block may be performed based on the comparison indicating that the first measured value is different from the second measured value by more than a predetermined threshold.

As another example, the set of components may include a two-input component that includes a first input and a second input. In this example, the first configuration may tie the first input and the second input to a supply voltage, the second configuration may tie the first input to the supply voltage and the second input to ground, a third configuration corresponding to a third test vector on the test vector bus may tie the first input to ground and the second input to the supply voltage, and a fourth configuration corresponding to a fourth test vector on the test vector bus may tie the first input and the second input to ground. The detecting of the defect in the test block may then be further performed based on one or more comparisons involving a third current drawn by the test block when the set of components is in the third configuration and a fourth current drawn by the test block when the set of components is in the fourth configuration.

As another example, the detecting of the defect in the test block may be performed by a test controller that is integrated into the self-testing circuit. Additionally or alternatively, the detecting of the defect in the test block may be performed by a test controller that is integrated into a testing device separate from the self-testing circuit.

In another general aspect, a self-testing circuit may include a plurality of test blocks, a current measurement circuit, and a test controller that is electrically connected to the plurality of test blocks and the current measurement circuit. The plurality of test blocks may include a test block configured to receive a first test vector and a second test vector. The first test vector may correspond to a first configuration for a set of components in the test block and the second test vector may correspond to a second configuration for the set of components. The current measurement circuit may be configured to measure a first current drawn by the test block when the set of components is in the first configuration. The current measurement circuit may be further configured to measure a second current drawn by the test block when the set of components is in the second configuration. The test controller may be configured transmit the first test vector and the second test vector to the test block and to detect a defect in the test block based on a comparison between the first current and the second current.

In some implementations of the self-testing circuit, a variety of additional elements and/or features may be employed. As one example, the self-testing circuit may further include a set of switches within the test block. The set of switches may be configured to produce: the first configuration for the set of components when a first setting for the set of switches is applied, the first setting determined based on the first test vector; and the second configuration for the set of components when a second setting for the set of switches is applied, the second setting determined based on the second test vector.

As another example, the self-testing circuit may include an enable input for the test block. In this example, the test block may be configured, when the enable input is active, to allow the set of components in the test block to be put in a new configuration. When the enable input is inactive, the test block may then be configured to disallow the set of components in the test block from being put in the new configuration (and to put the set of components instead into a configuration associated with normal operation of the test block).

As another example, the self-testing circuit may further include an analog-to-digital converter circuit configured to convert the first current to a first value and the second current to a second value; and a memory configured to store the first value and the second value. In this example, the comparison between the first current and the second current may be performed by comparing the first value and the second value as stored in the memory.

In another general aspect, a non-transitory computer-readable medium stores instructions that, when executed, cause a test controller associated with a self-testing circuit to perform a process. The process may include transmitting, to a test block of a plurality of test blocks in the self-testing circuit, a first test vector corresponding to a first configuration for a set of components in the test block. The process may further include transmitting, to the test block, a second test vector corresponding to a second configuration for the set of components, the second configuration being different from the first configuration. The process may further include detecting a defect in the test block based on a comparison between a first current and a second current, where the first current is drawn by the test block when the set of components is in the first configuration and where the second current is drawn by the test block when the set of components is in the second configuration.

In some implementations of the non-transitory computer-readable medium, a variety of additional elements and/or features may be employed. As one example, the process may further include determining, based on the first test vector, a first setting for a set of switches within the test block, the set of switches configured to produce the first configuration for the set of components when the first setting is applied; and determining, based on the second test vector, a second setting for the set of switches, the set of switches configured to produce the second configuration for the set of components when the second setting is applied.

The details of these and other implementations are set forth in the accompanying drawings and the description below. Other features will also be apparent from the following description, drawings, and claims.

### BRIEF DESCRIPTION OF THE DRAWINGS

FIGS. 1A-1B show illustrative implementations of a self-testing circuit configured for current-based built-in self-test in accordance with principles described herein.

FIGS. 2-3 show illustrative methods for performing current-based built-in self-test for circuit components arranged in varied configurations in accordance with principles described herein.

FIG. 4 shows an illustrative current measurement circuit in accordance with principles described herein.

FIG. 5 shows illustrative current comparisons that may be performed to detect a defect in a test block in accordance with principles described herein.

FIG. 6 shows a plurality of illustrative test blocks that each include respective sets of components that can be arranged in varied configurations in accordance with principles described herein.

FIGS. 7A-7F show various aspects of how an illustrative set of switches within a test block may be configured with different settings to produce varied configurations for a set of components in the test block in accordance with principles described herein.

FIGS. 8A-8H show an extended example of how certain components within an illustrative test block may be arranged in varied configurations and tested using current-based built-in self-test principles described herein.

### DETAILED DESCRIPTION

Current-based built-in self-testing for circuit components arranged in varied configurations is described herein. As mentioned above, various challenges are associated with testing intricate circuitry produced using modern semiconductor manufacturing processes. These challenges may be particularly pronounced for testing analog blocks of circuitry (since digital logic circuits may be more efficiently tests using scan chains, automatically-generated test patterns, etc.), and testing for manufacturer defects in the analog blocks (as opposed to performing parametric measurement for the blocks and/or other types of tests). As will be described herein, these and other challenges may be efficiently and effectively addressed by methods and systems for current-based built-in self-test for analog circuit components that are arranged in varied configurations in accordance with principles described herein.

During the manufacturing process, multiple instances of a particular circuit may be produced on a single semiconductor wafer. These individual circuits may be referred to as dies and, when separated and packaged (and possibly combined with other circuitry within a unified package), these packaged dies may be referred to as chips. Electronic chips may be sold as a final product themselves or may be included along with other discrete components (other chips, passive electronic components, power supplies, etc.) on circuit boards that are embedded in electrical or electronic devices that themselves are sold as final products. In any event, a single wafer may include a large number of individual circuits (dies) that need to be thoroughly tested, such that conventional testing techniques involving external testing equipment may be insufficient or sub-optimal for testing all of the circuits on all of the wafers that may be produced by a given fabrication facility. For example, while external testing equipment may be configured to produce stimulation for each individual circuit, as well as to measure and analyze output responsive to this stimulation for various tests, this testing approach may be inconvenient and inefficient, may take an overly long time to assure suitable test coverage, may be costly in terms of necessary test equipment and the space it uses up on the manufacturing floor, and so forth.

Built-in self-test (BIST) techniques have been developed as a response to the challenges described above. The idea of built-in self-test is that certain aspects of the test equipment that would otherwise be implemented external to the circuits under test may instead by integrated into the circuits themselves, such that at least some test stimulation may be generated, measured, and analyzed using built-in circuitry on the dies themselves, rather than using external test equipment. Conventional BIST techniques can be useful for quickly and efficiently ensuring that circuits perform as expected when receiving typical input stimulation. However, these techniques are not generally able to provide thorough defect test coverage of individual components within the circuit, since each component is only tested to the extent that it operates in connection with the circuit as a whole. It would therefore be desirable, especially for circuits that are to be used in high-stakes situations where reliability is crucial (e.g., for automotive products, etc.), to test individual components within each circuit and to do so with the similar efficiency (e.g., low cost, short test time, etc.) as provided by conventional BIST approaches.

To this end, current-based built-in self-test is described herein for efficiently testing circuit components arranged in varied configurations. Rather than (or in addition to) stimulating the input and analyzing the output of portions of a circuit in its normal operational configuration, as a conventional BIST approach might do, methods and systems described herein perform current-based BIST on individual components (particularly analog components) and small groups of components in configurations other than the configuration in which the components will be arranged during normal operation of the circuit. More specifically, as will be described and illustrated in more detail below, a set of components within a particular test block (of a plurality of test blocks included in a given self-testing circuit) may be arranged and rearranged in a variety of different configurations aimed at exposing potential manufacturing defects in the various components if such defects exist. For each different configuration, a current drawn by the test block may be measured and stored. Defects may then be detected when these measured currents do not align as expected. For example, two configurations may be set up such that, if no defect is present, similar currents would be expected to be drawn (e.g., identical resistors on parallel branches of the test block could be tested in the two configurations as one example). Comparing the current drawn by the test block in these two configurations could then indicate that a defect is present if the measured currents are too different from one another.

While designing each test block to be flexibly reconfigurable to support a variety of configurations associated with a variety of different tests may require some additional design effort on the front end, the overall cost added to the circuit (e.g., to add switches and other circuitry making the test blocks reconfigurable) is minimal and generally well worth the increase in test efficiency and BIST coverage that is achievable by using these techniques. Specifically, once each self-testing circuit is designed and manufactured, testing of the circuit may be performed largely or exclusively using the built-in test circuitry on the die, with less or no reliance on external testing equipment. This may lead to more thorough test coverage even as test times and associated test costs come down significantly. Various benefits thus may result from methods and systems for current-based built-in self-test described herein, including at least: a high defect coverage, a short test time, a reduced measurement complexity (reducing or eliminating measurements taken and analyzed to current consumption measurements that are straightforward on-chip and less reliant on external equipment, reducing observations to one observation point per test block, etc.), a high reliability with both high and low impedance nodes, a reduced or eliminated need for dynamic part average testing (DPAT) since ratios between different measurements can be used, a reduced number of stimulation signals needed (e.g., using just few digital signals, serial configuration of test shift register possible, etc.), a high test parallelism potential due to the reduction or elimination of special automated test equipment relied on, a unified testing methodology for various types of test blocks (e.g., different types of analog blocks with different types and arrangements of electrical components), and so forth.

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Current-based built-in self-test for circuit components arranged in varied configurations may result in any or all of the technical benefits mentioned above, as well as various additional technical benefits that will be described and/or made apparent below.

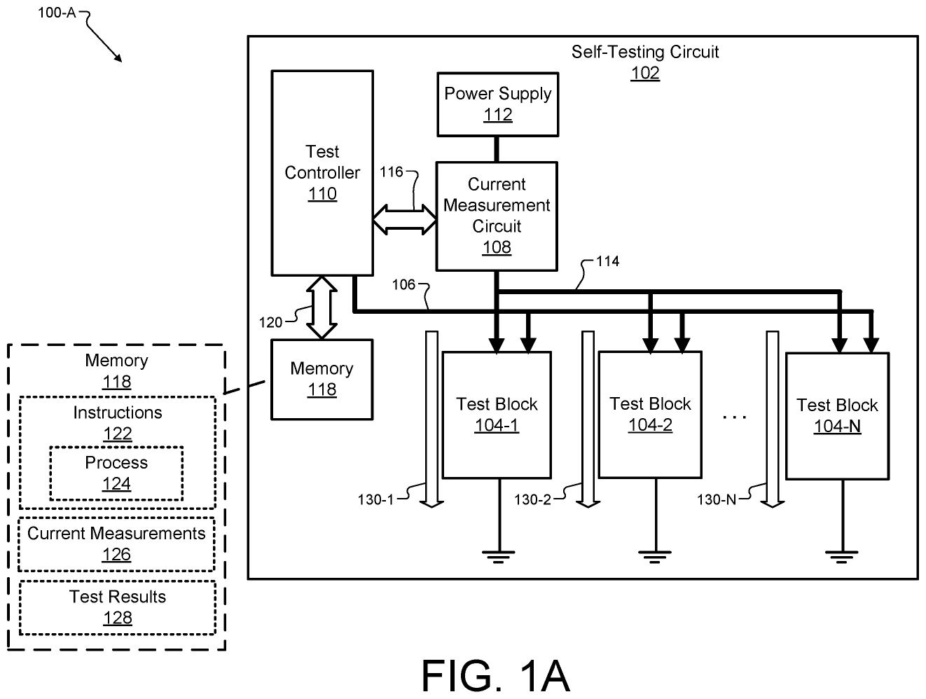

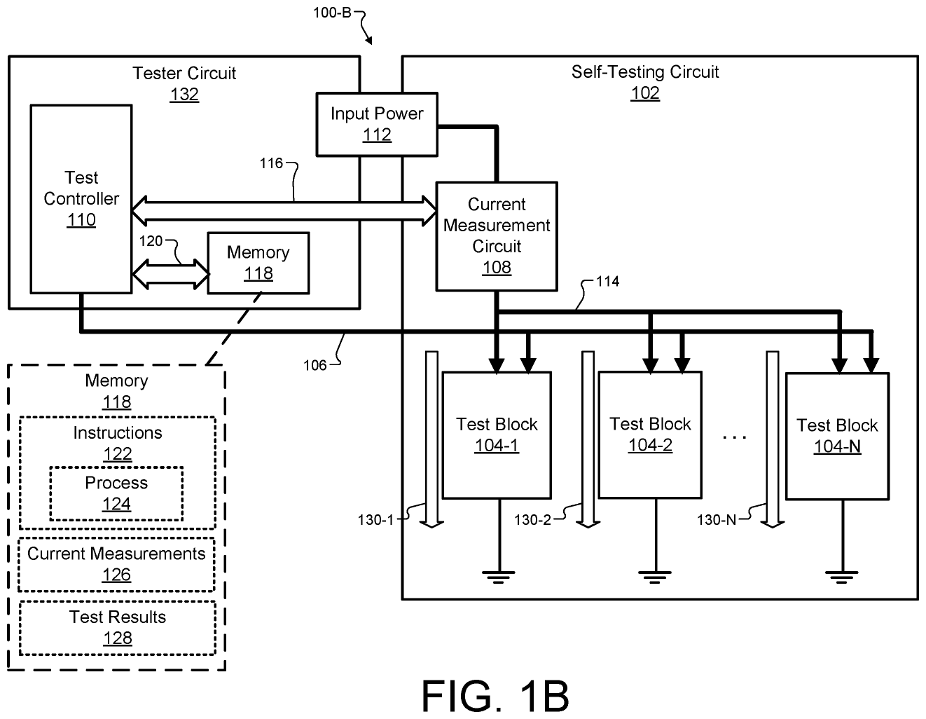

FIG. 1A shows an illustrative implementation 100-A of a self-testing circuit 102 configured for current-based built-in self-test in accordance with principles described herein. Self-testing circuit 102 may represent any unit of electronic circuitry as may serve a particular implementation. For example, self-testing circuit 102 may correspond to a single die on a wafer that is manufactured to include a number of similar or identical dies. As such, self-testing circuit 102 may be thought of as an electronic chip configured to perform various analog and/or digital functions (though certain chip elements, such as those related to packaging the die, are not shown). In other examples, self-testing circuit 102 could correspond to a portion of circuitry on a die, to the circuitry of more than one die, or to some other unit of electronic circuitry as may serve a particular implementation. In some examples, self-testing circuit 102 may be implemented by a relatively simple circuit with only a few analog or digital blocks configured to perform relatively straightforward functions. In other examples, self-testing circuit 102 may be implemented by an extremely advanced or complex circuit with a large number of analog and/or digital blocks configured to perform a variety of simple and/or complex functions.

Self-testing circuit 102 may be configured, in accordance with principles described herein, to reconfigure test blocks (e.g., analog blocks) to multiple non-functional test modes for which expected current consumption has been defined, or at least for which expected ratios or disparities with current consumptions for other test modes have been defined. For example, a predesignated testing plan for a particular self-testing circuit may lay out various tests that are to be performed (e.g., including test vectors to be used for each test block) and various current ratios and/or discrepancies between tests that are to be analyzed in order to detect potential defects. The reconfiguration of these test blocks may be performed in such a way that potential defects would manifest themselves in changes to measured current consumption and/or changes to the comparisons between different measured current consumptions. Based on these principles, current-based BIST techniques may be used to rearrange circuit components to various configurations and to sequentially check all internal structures (e.g., circuit components, groups of components, etc.) as part of a BIST procedure.

To bring current-based BIST into effect, implementation 100-A of self-testing circuit 102 is shown to include a plurality of test blocks 104 labeled individually as test blocks 104-1, 104-2, and 104-N. These test blocks 104 represent simpler units of circuitry with narrower functions than self-testing circuit 102 as a whole, but it will be understood that each test block 104 may itself include a set of components (e.g., analog and/or digital electrical components such as resistors, capacitors, transistors, operational amplifiers, combinational logic gates, registers, etc.) that are configured to operate collectively to perform a certain function. Specific examples of test blocks 104 will be illustrated and described in detail below. An ellipsis before test blocks 104-N is shown to indicate that any suitable number, N, of test blocks may be included in a particular self-testing circuit (e.g., included on a particular die for a particular chip). For instance, certain implementations could include dozens, hundreds, or thousands of test blocks, depending on the complexity, purpose, and design of the self-testing circuit 102.

Along with test blocks 104, implementation 100-A of self-testing circuit 102 is further shown to include a test vector bus 106 electrically connecting the plurality of test blocks 104, as well as a current measurement circuit 108 and a test controller 110. Each of these elements will be described and illustrated in more detail below.

FIG. 1A illustrates that current measurement circuit 108 may measure current that is drawn or consumed from a power supply 112 by test blocks 104 as each is powered by a voltage rail 114 that originates from power supply 112 and can be monitored by current measurement circuit 108 (e.g., to detect how much current is being drawn from voltage rail 114 by any test blocks that are actively consuming current). FIG. 1A further illustrates that test controller 110 is communicatively coupled to current measurement circuit 108 by way of a communication interface 116 and to a memory 118 by way of a communication interface 120.

As shown in a dashed-line box connected to the representation of memory 118 within self-testing circuit 102, memory 118 may be used to store various types of data for various purposes related to the current-based BIST. For example, as shown, memory 118 may implement a non-transitory computer-readable medium that stores a set of instructions 122 that, when executed, cause test controller 110 to perform a process 124 that will be described in more detail below. More generally, instructions 122 may be based on a testing plan for the self-testing circuit, which may incorporate a variety of measurements, comparisons, and other test-related information to assure suitable test coverage for the self-testing circuit. Memory 118 may further be used to store any number of current measurements 126 that have been made, test results 128 that have been determined (e.g., based on current measurements 126 themselves or based on comparisons of different current measurements 126, etc.), and/or any other suitable data as may serve a particular implementation. The communication interface 120 between test controller 110 and memory 118 will be understood to represent the movement of data between test controller 110 and memory 118. For example, communication interface 120 may be used to load instructions 122 for process 124, to store current measurements 126 that have been measured by current measurement circuit 108, to load current measurements 126 for analysis by test controller 110, to store test results 128 that have been determined, and so forth.

Similar to communication interface 120, communication interface 116 between test controller 110 and current measurement circuit 108 may serve as an interface for data transfer between these components. Test controller 110 may use communication interface 116 to trigger current measurement circuit 108 to make certain current measurements at certain times (e.g., when certain test vectors are driven onto test vector bus 106 by test controller 110, when certain test blocks are active in a particular configuration so as to be drawing current from voltage rail 114, etc.). Test controller 110 may also use communication interface 116 to receive current measurements from current measurement circuit 108, which test controller 110 may then use to perform defect analysis for the built-in self-test (e.g., possibly after storing and loading the current measurements from memory 118).

In operation, test controller 110 may use test vector bus 106 to transmit a first test vector and a second test vector to all the test blocks 104. However, only one particular test block of the plurality of test blocks 104-1 may be active at a time (e.g., implemented using enable lines described in more detail below and not shown in FIG. 1A). For example, test block 104-1 may be enabled as the block-under-test during one phase of the testing when the first and second test vectors are transmitted. In this case, the first test vector could correspond, for instance, to a first configuration for a set of components in test block 104-1 (e.g., electronic components not explicitly shown in FIG. 1A) and the second test vector could correspond to a second configuration (e.g., a different configuration than the first configuration) for the set of components in test block 104-1.

While test controller 110 is shown to transmit these test vectors by way of test vector bus 106 in this example (and other examples described herein), it will be understood that a shared test vector bus such as test vector bus 106 and corresponding enable lines is not the only way that a test controller may communicate test vectors to the plurality of test blocks in a given self-testing circuit. For example, another way to direct test block components of different test blocks into desired test configurations (e.g., especially for a self-testing circuit with a relatively small number of test blocks) may be to have some number of non-shared test vector lines connecting test controller 110 and each test block 104. In this type of configuration, no enable lines would be necessary, since a particular value (e.g., all lines at ‘0’ or low) could indicate that the test block is to be in a configuration corresponding to normal operation (i.e., not enabled for test) and other values (e.g., non-zero test vectors) could indicate that the test block is to be in a particular test configuration such as the first or second configurations described above (i.e., enabled for test). In these types of implementations, it will be understood that there need not be the same number of test vector lines going from the test controller to each test block (though, in some implementations, this could be the case). For example, if a first test block had a small number of desired test configurations, there may be fewer test vector lines going to that test block than one that has a larger number of desired test configurations.

Once the first test vectors has been transmitted to test block 104-1 and the components of test block 104-1 have been put into the first configuration, current measurement circuit 108 may be configured to measure a first current that is drawn by test block 104-1 when the set of components is in the first configuration (e.g., and possibly when the first test vector is on test vector bus 106). Specifically, as shown, a current 130-1 represents current drawn from voltage rail 114 (i.e., consumed from power supply 112) by test block 104-1, while other currents 130 are similarly shown for the other test blocks (i.e., a current 130-2 drawn by test block 104-2, a current 130-N drawn by test block 104-N, etc.). It will be understood that since those other test blocks are not enabled in the present example (since test block 104-1 is the block-under-test for this particular example), these other currents 130-2 and 130-N will be zero and all the current measured by current measurement circuit 108 will be associated with current 130-1 drawn by test block 104-1 (e.g., current drawn by the components in the first configuration in test block 104-1 for this first measurement). At a subsequent time, current measurement circuit 108 may then measure a second current drawn by test block 104-1 when the set of components in test block 104-1 is in the second configuration (e.g., and possibly when the second test vector is on test vector bus 106). In this example, current measurement circuit 108 may therefore measure current 130-1 again, though a different test vector has been communicated (e.g., by way of test vector bus 106) for this second measurement.

Test controller 110 is shown to be electrically connected both to test vector bus 106 (e.g., so as to allow test controller 110 to transmit appropriate test vectors on the bus with timing set forth by a test plan built into instructions 122) as well as to current measurement circuit 108 (e.g., so as to allow test controller 110 to receive measurement results, to direct measurements to be made or measurements to be converted to digital values, etc.). As will be described in more detail below, test controller 110 may be configured to detect one or more defects in the test blocks 104 based on comparisons between currents that have been measured. For example, test controller 110 could detect a defect in test block 104-1 based on a comparison between the first current and the second current described above.

Test controller 110 may perform any suitable operations to effect current-based built-in self-test in accordance with principles described herein. For example, in one implementation, the instructions 122 for the process 124 may cause test controller 110 to: 1) transmit (e.g., on test vector bus 106 or by way of another suitable electrical connection such as the non-shared test vector lines described above) a first test vector corresponding to a first configuration for a set of components in test block 104-1 of the plurality of test blocks 104; 2) transmit a second test vector corresponding to a second configuration for the set of components (where the second configuration is different from the first configuration); and 3) detect a defect in test block 104-1 based on a comparison between a first current and a second current, where the first current is drawn by test block 104-1 when the set of components is in the first configuration (e.g., when the first test vector is on test vector bus 106), and where the second current is drawn by test block 104-1 when the set of components is in the second configuration (e.g., when the second test vector is on test vector bus 106).

As will be described and illustrated in more detail below, self-testing circuit 102 may perform this process 124 and similar methods and processes described herein, using additional elements that are not explicitly shown in FIG. 1A. For example, certain implementations of self-testing circuit 102 may include a set of switches within test block 104-1 (e.g., as well as other respective sets of switches within the other test blocks 104). The set of switches may be configured to produce the first configuration for the set of components when a first setting for the set of switches (a setting determined based on the first test vector) is applied. The set of switches may also be configured to then produce the second configuration for the set of components when a second setting for the set of switches (a setting determined based on the second test vector) is applied.

Additionally, self-testing circuit 102 may further include an enable input for test block 104-1 (e.g., as well as other respective enable inputs for each of the other test blocks 104) and/or other suitable signaling lines (e.g., power down lines for each test block to disallow current from being drawn from test blocks that are not under test when another test block is under test, etc.). The test block may be configured such that, when the enable input is active, the set of components in the test block is allowed to be put in a new configuration (e.g., to be reconfigured, for instance, from the first configuration to the second configuration). Moreover, when the enable input is inactive, the set of components in test block 104-1 may be disallowed from being put in the new configuration. Other mechanisms (e.g., a power down input, not explicitly shown) may also be used to disallow current from being drawn by test block 104-1. Self-testing circuit 102 may further include an analog-to-digital converter circuit configured to convert measured current into digital values that may be stored in memory 118 as current measurements 126. For example, an analog-to-digital converter circuit within self-testing circuit 102 (not explicitly shown) may convert the first current to a first value and the second current to a second value such that memory 118 may store the first value and the second value and the comparison between the first current and the second current analyzed by test controller 110 may be made by comparing the first value and the second value as stored in memory 118.

As shown in FIG. 1A and as has been described, each test block 104 may be thoroughly tested using current-based BIST in which a variety of currents are measured when the test blocks are in a variety of different electrical configurations (e.g., with their components wired in different arrangements, etc.), and these currents are compared with one another according to a predesignated testing plan. In some implementations, sufficient test coverage may be achieved in this way, using this current-based built-in self-testing exclusively. In other examples, it will be understood that external test equipment may also be used in combination with the built-in self-testing described herein. Even in these cases in which a combination of BIST and external testing are relied on, it will be understood that the external equipment needed, the time used for external testing, the costs associated with the external testing, and so forth, may all be significantly reduced as a result of efficient current-based built-in self-testing implemented in accordance with principles described herein.

In the example of implementation 100-A, the detecting of the defect in the test block is shown to be performed by a test controller that is integrated into the self-testing circuit. That is, test controller 110 is shown in FIG. 1A to be built into self-testing circuit 102 so as to direct testing for test block 104-1 (as has been described) and for each of the other test blocks in the plurality of test blocks 104. In some examples, software for performing these various tasks (e.g., instructions 122 embodying process 124, etc.) may be received from an external source (e.g., from a test device or other testing equipment), but the microprocessor implementing this software may still be integrated into the self-testing circuit 102 itself.

In contrast, FIG. 1B shows another implementation of self-testing circuit 102 in which test controller 110 is not integrated into the self-testing circuit. Specifically, as shown, an illustrative implementation 100-B of self-testing circuit 102 may be configured such that the detecting of defects in the various test blocks 104 may be performed by a test controller that is integrated into a testing device separate from the self-testing circuit. For example, as shown in illustrative implementation 100-B, self-testing circuit 102 may still include the plurality of test blocks 104, test vector bus 106, and current measurement circuit 108, while test controller 110 and/or memory 118 may be implemented by a tester circuit 132 that is separate from self-testing circuit 102 (e.g. inside automatic test equipment performing the testing). In this example, power supply 112 is drawn as being distributed between both self-testing circuit 102 and tester circuit 132 to suggest that input power drawn from power supply 112 for voltage rail 114 may originate either on self-testing circuit 102 (as described above in relation to implementation 100-A) or on tester circuit 132 (which may provide both power and direction for testing self-testing circuit 102 in this implementation). Just as other test vector communication interfaces (other than the shared test vector bus 106) were described above in relation to FIG. 1A, it will be understood that test vectors may be communicated by test controller 110 by way of test vector bus 106 or other suitable interfaces in the tester circuit configuration of FIG. 1B. As one other example interface, for instance, a JTAG communication interface (controlled by a JTAG TDR) may be used by a controller in a tester circuit to limit the number of electrical interconnections between the tester circuit and the self-testing circuit.

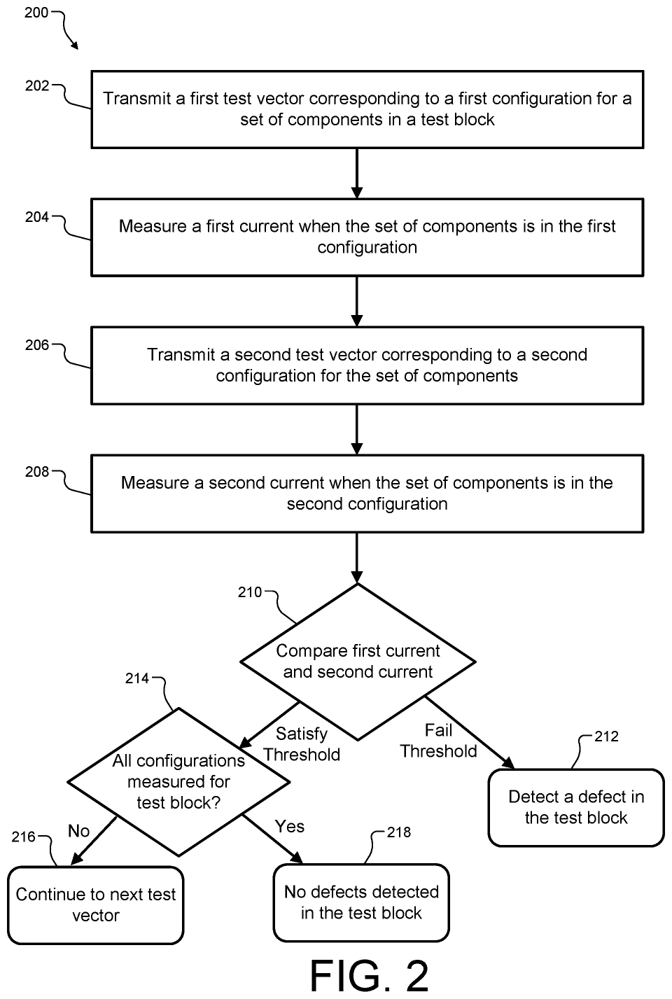

FIG. 2 shows an illustrative method 200 that, similar to process 124, may be used to perform current-based BIST for circuit components arranged in varied configurations in accordance with principles described herein. While FIG. 2 shows illustrative operations 202-218 according to one implementation, other implementations of method 200 may omit, add to, reorder, and/or modify any of the operations 202-218 shown in FIG. 2. In some examples, multiple operations shown in FIG. 2 or described in relation to FIG. 2 may be performed concurrently (e.g., in parallel) with one another, rather than being performed sequentially as illustrated and/or described. Each of operations 202-218 will now be described in more detail as the operations may be performed by an implementation self-testing circuit 102 (e.g., one of implementations 100-A or 100-B).

At operation 202, a self-testing circuit may transmit a first test vector to a test block of a plurality of test blocks in the self-testing circuit (e.g., by way of a test vector bus that is electrically connected to the plurality of test blocks or by way of another suitable communication interface such as described above). The first test vector may correspond, for example, to a first configuration for a set of components in a particular test block of the plurality of test blocks. For example, in the example of implementation 100-A of self-testing circuit 102, the particular test block may be test block 104-1 and the first test vector may be transmitted by test controller 110 on test vector bus 106. Upon receiving this first test vector (and, in certain examples, upon being activated or enabled by way of an enable input included in test block 104-1), test block 104-1 may be configured to electrically rearrange its components (e.g., by way of setting a plurality of switches or in other suitable ways) into the first configuration. At this point, a certain amount of current 130-1 will be drawn from voltage rail 114.

Accordingly, at operation 204, the self-testing circuit (e.g., current measurement circuit 108) may measure a first current drawn by the test block when the set of components is in the first configuration. For example, with the first test vector on test vector bus 106, current measurement circuit 108 may measure current 130-1 to determine the current consumption of test block 104-1 with its components in the first configuration.

At operation 206, the self-testing circuit may then transmit to the test block a second test vector corresponding to a second configuration for the set of components. This second configuration may be different from the first configuration, such that, for example, upon receiving this second test vector (and, in certain examples, upon being activated or enabled by way of an enable input included in test block 104-1), test block 104-1 may be configured to again rearrange its components, this time from the first configuration into the second configuration. At this point, another amount of current 130-1 (which may be expected to be approximately the same as the first current or to otherwise have a predetermined relationship with the first current) will be drawn from voltage rail 114.

Accordingly, at operation 208, the self-testing circuit (e.g., current measurement circuit 108) may measure a second current drawn by the test block when the set of components is in the second configuration. For example, current measurement circuit 108 may again measure current 130-1 to determine the current consumption of test block 104-1 with its components in the second configuration.

At operation 210, the self-testing circuit may compare the first current measured at operation 204 and the second current measured at operation 208. This comparison may be performed in a variety of ways that will be described, including, for example, by determining a difference between the currents (using a subtraction operation) or by determining a ratio of the currents (using a division operation). The comparison between the first and second currents may then be compared to some expectation that has been predetermined. For instance, if it is expected that the first and second configurations should produce the same amount of current draw, a difference between the compared currents may be expected to be near zero while a ratio of the compared currents may be expected to be near one. If a threshold associated with this expectation is not met, flow may proceed to operation 212 (“Fail Threshold”), while, if the threshold is met, flow may proceed to operation 214 (“Satisfy Threshold”).

At operation 212, the self-testing circuit may detect a defect in the particular test block that is being tested (e.g., test block 104-1 in the example above). For example, since the first and second currents did not satisfy a threshold associated with the expected relationship between the currents, test controller 110 may be configured to determine that some defect within the test block has likely compromised one of the currents in some way, thus indicating that the test block has some sort of defect and should be marked as such.

Conversely, at operation 214, the self-testing circuit may determine that no defect has been detected yet, and determine if all the configurations for the current block-under-test have been tested or if there are additional configurations and tests to perform. If there are still more configurations to test (“No”), flow proceeds to operation 216, which may lead to performing some or all of method 200 again with new test vectors, configurations, measurements, and/or comparisons as may be called for in a predesignated testing plan. On the other hand, if all the configurations have been tested for the current block-under-test (“Yes”), flow may proceed to operation 218, where the self-testing circuit may determine that no defects are detected in the block-under-test (e.g., test block 104-1 in this example). In accordance with the testing plan, the self-testing circuit may then proceed to perform method 200 for additional test blocks 104, or, if all the blocks have been tested, may make a final assessment of the self-testing circuit and its defects (if any).

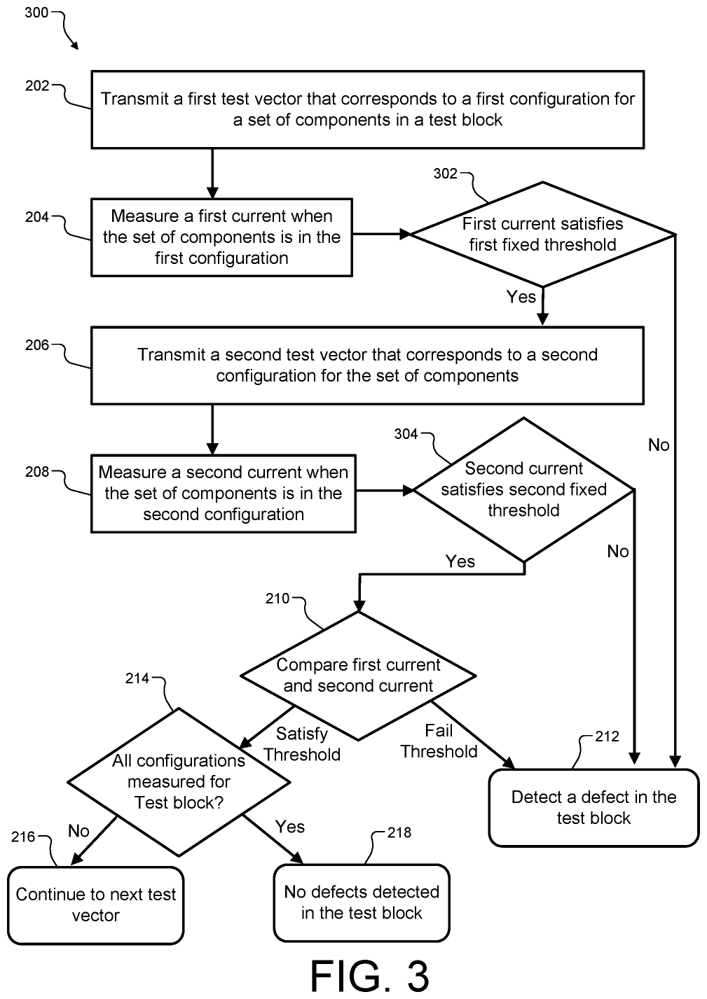

FIG. 3 shows an additional illustrative method 300 for performing current-based built-in self-test for circuit components arranged in varied configurations in accordance with principles described herein. As shown, method 300 includes all the same operations 202-218 as described above in relation to FIG. 2. Additionally, method 300 includes a few additional operations 302 and 304 that will now be described. It will be understood that these operations may be optional in the sense that they may increase the efficiency and/or effectiveness of the current-based built-in self-testing for certain self-testing circuits, for certain test blocks, and/or under certain circumstances. For other self-testing circuits, other test blocks, and/or under other circumstances, however, operations 302 and 304 may not be particularly helpful in light of the comparison at operation 210, and may thus be omitted (as with the example of method 200).

Operation 302 is shown to be performed in response to the measuring of the first current at operation 204 and prior to the transmitting of the second test vector at operation 206. At operation 302, a determination is made whether the first current satisfies a first fixed or absolute threshold (as opposed to being judged relative to another current as will be performed at operation 210). For example, if the first current is expected to be somewhere between 100 uA and 200 uA but it falls far outside of this range (e.g., near 0 uA or 1 mA), test controller 110 may determine on that basis alone that a defect is present (hence, flow is shown to move directly from operation 302 to operation 212 in that case (“No”)). Conversely, if the first current is within the expected range, or at least within a predetermined threshold thereof, flow may continue on to operation 206 (“Yes”).

Operation 304 is shown to be performed in response to the measuring of the second current at operation 208 and prior to the comparing of the first and second currents at operation 210. Similar to operation 302, at operation 304, a determination is made whether the second current satisfies a second fixed or absolute threshold (as opposed to being judged relative to another current as will be performed at operation 210). For example, if the second current is expected to be somewhere between 100 uA and 200 uA but it falls far outside of this range (e.g., near 0 uA or 1 mA), test controller 110 may determine on that basis alone that a defect is detected (hence, flow is shown to move directly from operation 304 to operation 212 in that case (“No”)). Conversely, if the second current is within the expected range, or at least within a predetermined threshold thereof, flow may continue on to operation 210 (“Yes”), where the comparison may be made and the analysis described above may be performed.

It will be understood that operations 302 and 304 may serve as shortcuts in the flow of method 300 for cases in which a highly evident defect happens to be present. For example, if the defect can be detected based on operation 302 or even operation 304, time used to perform the operations following these may be saved. In implementations that include these shortcut operations, they may not be used to catch all the potential defects. For example, a defect could be detected in a first test block (e.g., test block 104-1) using the comparison analysis (e.g., using operation 210 rather than operation 302 or operation 304). Then, when the self-testing circuit moves on to test the next test block (e.g., test block 104-2) the self-testing circuit may detect a defect there using these shortcuts. More particularly, for example, test controller 110 may transmit, to test block 104-2, a third test vector corresponding to a particular configuration for an additional set of components in test block 104-2. Current measurement circuit 108 may then measure a third current drawn by test block 104-2 when the additional set of components is in the particular configuration. Using the shortcut illustrated with operation 302, test controller 110 may detect a defect in test block 104-2 based on the third current without a comparison to another current. That is, the defect in test block 104-2 may be determined based on the failure of the third current to satisfy the fixed, absolute threshold. For example, the detecting of the defect in test block 104-2 may include determining that the third current indicates a short condition in test block 104-2 (e.g., if the third current is far larger than an expected range) or determining that the third current indicates a disconnect condition in test block 104-2 (e.g., if the third current is near zero or far smaller than an expected range). The shortcuts provided by operations 302 and 304 may also help improve test coverage (e.g., ensuring that absolute current should be in a predefined range) and/or mitigate certain current ratio computation challenges (e.g., if a measured current would be zero such that calculating a ratio would result in dividing by zero, operations 302 and 304 would still be able to correctly handle the threshold comparison).

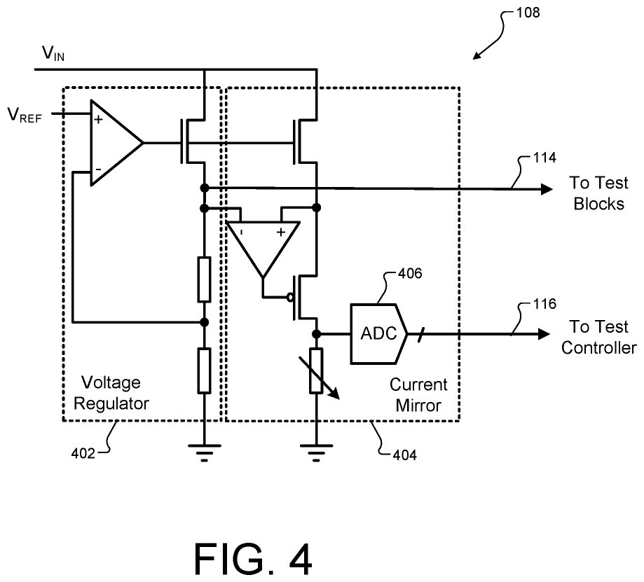

FIG. 4 shows an illustrative implementation of the current measurement circuit 108 described above. Specifically, as shown, the circuit implementing current measurement circuit 108 in this example receives an input voltage (VIN) from a power supply (not explicitly shown in FIG. 4) such as power supply 112 described above. An analog block on the left side of the circuit is labeled as a voltage regulator 402, while another analog block on the right side of the circuit is labeled as a current mirror 404. Together, these blocks form a current measurement circuit 108 that both provides a regulated voltage rail 114 to the test blocks 104 (as described and illustrated above), and that performs current sensing in furtherance of the various current consumption measurements that have been described.

As shown, output transistors at the top of voltage regulator 402 and current mirror 404 may be similarly situated and may be a same type of transistor. For example, with the transistor in the voltage regulator 402 acting as an output transistor, the other transistor in current mirror 404 may be implemented as a smaller duplicate of the output transistor that receives the same voltage and produces a copy of the output current that can be measured. Also shown is an amplifier that is configured to ensure that the voltages on the output node (i.e., voltage rail 114 that goes “To Test Blocks”) and the current sensing node connected to an analog-to-digital converter (“ADC”) circuit 406 are the same. In this way, the output current delivered to the output node (e.g., drawn by whichever test block 104 is presently active and enabled under test) is copied or mirrored with a known ratio that, when scaled by the current resistor (e.g., to convert current into voltage), allows ADC circuit 406 to determine a value representative of the current presently being drawn from the output (i.e., from voltage rail 114) by the test blocks.

One useful aspect of this type of design is that each current that is measured using current measurement circuit 108 may be converted to a digital value that can be used immediately or stored for later analysis as the situation may call for. For example, referring to the first and second currents described in examples above where test block 104-1 is reconfigured to test different current draws with different electrical configurations (e.g., as described, for example, in relation to operations 202-208 in FIGS. 2 and 3), the method may further include an operation for converting, using ADC circuit 406, the first current to a first value and the second current to a second value. The method may then include storing the first value and the second value in a memory such as memory 118. In this example, the comparison between the first current and the second current (e.g., performed as part of operation 210, as described above), may then be performed by comparing the first value and the second value as stored in the memory. For example, the first and second values may be immediately compared by test controller 110 or stored with other values in the memory (e.g., values associated with other configurations, other test blocks, other dies on the same wafer, etc.) for later comparisons and analysis as will be described in more detail below.

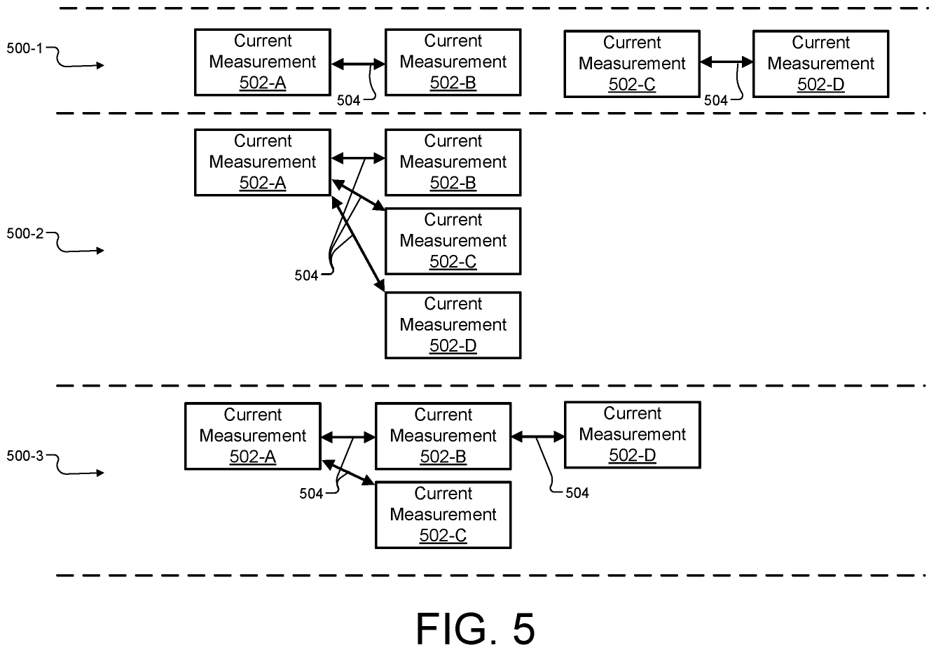

FIG. 5 shows various illustrative current comparisons that may be performed to detect a defect in a test block in accordance with principles described herein. Specifically, as shown, a particular testing plan may call for different types of comparisons between or among whatever different current measurements have been made (e.g., by current measurement circuit 108 as has been described). To illustrate a few example comparisons, FIG. 5 shows several examples 500-1, 500-2, and 500-3, each of which involve various current measurements 502 (i.e., current measurement 502-A, 502-B, 502-C, and 502-D). Each of these current measurements 502 will be understood to represent a current consumption measured by a current measurement circuit such as current measurement circuit 108 when a particular test block is enabled (activated) and drawing current with its components in a particular configuration. As one example, current measurement 502-A could represent a first current drawn by a first test block (e.g., test block 104-1) while its set of components is arranged in a first configuration, current measurement 502-B could represent a second current drawn by the same first test block (e.g., test block 104-1) while its set of components is arranged in a second configuration, current measurement 502-C could represent a third current drawn by a different test block in the same self-testing circuit (e.g., test block 104-2) while its set of components is arranged in a particular configuration, and current measurement 502-D could represent a fourth current drawn by yet another test block in a different self-testing circuit (e.g., a test block corresponding to test block 104-1 but that is on a different die on the same wafer).

In other examples, each of the current measurements 502 could be associated with different configurations of a same test block, each of the current measurements 502 could be associated with a same configuration of corresponding test blocks on different self-testing circuits, each of the current measurements 502 could be associated with similar test blocks on the same self-testing circuit, and so forth. In this way, the comparisons made by the test controller may be highly varied and flexible to implement a thorough testing plan that provides a desirable amount of test coverage for each test block and self-testing circuit. For example, currents may be compared between different configurations within the same test block where the configurations are expected to draw similar amounts of current (e.g., two parallel branches). Currents may also be compared between equivalent test blocks on the same die (e.g., similar or identical test block on a single self-testing circuit).

In some examples, a dynamic part average testing (DPAT) method may be used, in which a tester circuit analyzes an entire wafer and then comparisons can be performed between corresponding test blocks on different dies within the wafer. For example, currents may be compared between identical circuits (e.g., test blocks) on different dies from the same wafer using such DPAT methods.

More particularly, referring back to method 200 and the first and second test vectors and configurations described in that example, a comparison between different test blocks within the same self-testing circuit may be performed by including additional operations in method 200. For example, method 200 may further include an operation for transmitting a third test vector corresponding to a particular configuration for an additional set of components in an additional test block of the plurality of test blocks in the self-testing circuit. Method 200 may further include an operation for measuring a third current drawn by the additional test block when the additional set of components is in the particular configuration. The detecting of the defect in the test block (e.g., at operation 210) may then be further based on a comparison between the first current and the third current in this example.

In like manner, a comparison between corresponding test blocks from different self-testing circuits may also be performed by including additional operations in method 200. For example, method 200 may further include an operation for transmitting the first test vector to an additional test block that corresponds to the test block and that is included within an additional plurality of test blocks in an additional self-testing circuit manufactured on a same wafer as the self-testing circuit. Method 200 may further include an operation for measuring a third current drawn by the additional test block when an additional set of components in the additional test block is in the first configuration. The detecting of the defect in the test block (e.g., at operation 210) may then be further based on a comparison between the first current and the third current.

Regardless of which particular self-testing circuits, test blocks, and configurations are represented by the various current measurements 502 that may be available (e.g., measured and stored at a previous time and then loaded from memory), FIG. 5 shows that a variety of different types of comparisons 504 between pairs or among groups of current measurements 502 may be performed, as may be directed by a preconfigured testing plan implemented, for example, in the software instructions (e.g., instructions 122). For instance, example 500-1 shows one comparison between current measurements 502-A and 502-B may be performed, and a separate comparison between current measurements 502-C and 502-D may also be performed. Example 500-2 shows that another testing plan (or another part of the same testing plan) may call for comparisons between current measurement 502-A and each of the other current measurements 502-B, 502-C, and 502-D. Example 500-3 then shows a situation where comparisons 504 between current measurement 502-A and each of current measurements 502-B and 502-C are performed, and where another comparison 504 between current measurement 502-B and measurement 502-D is also included. It will be understood that each of these comparisons are shown for illustrative purposes and that any number, combination, and arrangement of these types of one-to-one or one-to-many comparisons may be part of a given testing plan as may serve a particular implementation.

Additionally, while each comparison 504 is illustrated in the same way in the examples 500-1 through 500-3 in FIG. 5 (i.e., as double-headed arrows connecting two different current measurements 502), it will be understood that different types of comparisons of current values may be performed in different situations, such that different thresholding techniques or other defect analyses may be appropriate. As a first example, the comparing of a first value and a second value may include determining a ratio of the first value to the second value (e.g., by performing a division operation on the two values). Such ratios may be effective tools for defect testing since integrated circuit manufacturing is known to result in large absolute spreads of component values. When absolute current consumption is analyzed (as opposed to the relative consumption represented by a ratio), process and temperature spread may limit test coverage as wide limits or careful DPAT may be required. Conversely, by using the ratio of two measured current values, the process and temperature spread may be effectively canceled out so that narrower ranges may be checked and defect coverage is thereby improved. The detecting of a defect in the test block may include determining that the ratio falls outside a predetermined range. In some examples, it may be desired or expected that the ratio should be approximately 1, signifying that the two currents are expected to be equal. However, while relatively small ratios may be associated with the most reliable testing, the expected ratio or range need not be associated with a ratio of 1. In some comparisons 504, for example, the expected ratio may be 2, or 5, or 10, or some other relatively small ratio value. The thresholding range for these examples may give a small amount of leeway to the computed ratio while associating a more significant deviation with a detected defect. For example, if the expected ratio is 2, the range anticipated for the computed ratio may be 1.8-2.2 and any ratio outside of that may trigger the defect to be assumed.

As a second example, the comparing of a first value and a second value may include determining a difference between the first value and the second value (e.g., by performing a subtraction operation on the two values). In this case, the detecting of the defect in the test block may similarly include determining that the difference falls outside a predetermined range. However, the assumption in this case may be that the currents should be approximately equal, such that the predetermined range only allows for some small amount of non-zero difference (e.g., that the difference is less than 2 uA, or some other appropriate value given the currents expected).

As described above, measured currents may also be compared against fixed, absolute values that are expected. For example, if a current is expected to be in a range from 100-200 uA and the current is measured as being near 0 uA, it may be safely assumed that there is a disconnect or other defect in the circuit that should be flagged. For less prominent deviations, however (e.g., if the measured current in this example were closer to the 100 uA or 200 uA limits of its expected range), it will be understood that basing the defect analysis on relative comparisons between currents, rather than on absolute measured values, can increase the reliability of the testing and otherwise provide benefits. One reason for this is that each wafer may be manufactured under slightly different conditions or with slightly different parameters such that different process characteristics may affect the absolute currents drawn from wafer to wafer. Additionally, differences in temperature and/or other such circumstances when different tests are taken (e.g., when different currents are measured) may also have a significant effect on absolute measured values. As such, one measured value could be well within the expected range and still represent an anomaly or problem given the process and temperature dynamics at play, while another measured value could be on the outer margins of the expected range and be entirely benign when its particular process and temperature dynamics are properly accounted for.

Rather than trying to calculate and anticipate accurate expectations and ranges that account for these additional variables (e.g., process, temperature, etc.), methods and systems described herein rely on comparisons between current measurements where these variables are expected to remain relatively consistent so that they can therefore be assumed to cancel out or otherwise be rendered insignificant. These assumptions can generally be made for currents measured at the same temperature (e.g., around the same time when the temperature does not have much chance to drift) and for circuitry that is on either the same die or at least the same wafer (so as to have the same process characteristics). By limiting comparisons to current measurements where these assumptions can be made, test calibration and other efforts to account for temperature and process differences between tests may be mitigated or avoided entirely, thereby simplifying and reducing time and costs for the built-in self-testing described herein.

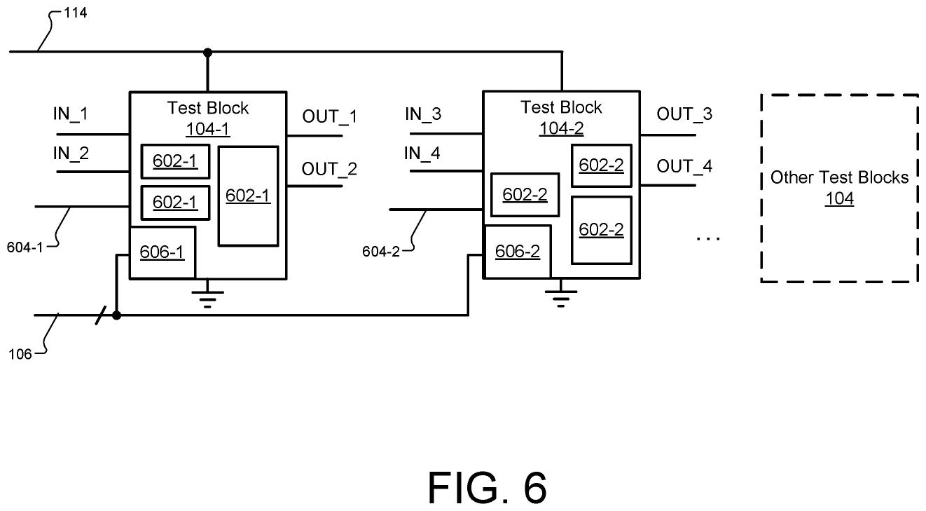

FIG. 6 shows illustrative implementations of test blocks 104 (e.g., test block 104-1, test block 104-2, etc.) that each include respective sets of components 602 configured to be arranged in varied configurations in accordance with principles described herein. More particularly, test block 104-1 is shown to include several components 602-1 and test block 104-2 is shown to include its own set of several components 602-2. While each of the components 602 depicted in FIG. 6 is drawn as a non-descript box in this illustration, it will be understood that these various components may represent different types of electronic components (e.g., resistors, capacitors, transistors, operational amplifiers, logic gates, etc.) that are configured to be rearranged into different configurations in the ways described herein. As such, the boxes representing the components 602 are shown to have different sizes, shapes, and placements in each of the test blocks, suggesting that varied components may be put into a variety of different configurations as described herein.

Each of test blocks 104 in FIG. 6 is also shown to interface with signals coming in and going out on various input and output terminals. For example, as has been described, voltage rail 114 is shown to provide input power to all the test blocks 104. Additionally, test vector bus 106 is shown to electrically connect each of test blocks 104 to a test controller (not shown in FIG. 6) that drives the test vector bus. As has been mentioned, respective enable inputs 604 are also shown to be inputs that each test block 104 receives. Specifically, test block 104-1 is shown to include an enable input 604-1 and test block 104-2 is shown to include an enable input 604-2. These enable inputs 604 may also be driven by a test controller such as test controller 110, such that only one particular block-under-test that is the current focus of the test controller's testing is enabled at a time. To this end, each of the test blocks 104 may be configured such that, when the enable input 604 is active, the test block allows its set of components 602 to be put in a new configuration. Conversely, when the enable input is inactive, the test block would then be configured to disallow its set of components from being put in the new configuration. As mentioned above, other inputs (e.g., power down lines, etc., not explicitly shown in FIG. 6) may also be used in connection with the enable inputs to control when current is allowed to be drawn or is disallowed from being drawn. For example, if enable input 604-1 is active at a given moment in time, enable input 604-2 may be inactive and the test blocks may be configured such that only components 602-1 of test block 104-1 are able to be reconfigured and/or allowed to draw any current from voltage rail 114. Later, when testing is to be performed respective to test block 104-2, enable input 604-2 may be active and enable input 604-1 may be inactive, such that only the components 602-2 in test block 104-2 are reconfigurable and able to draw any current from voltage rail 114.

Other input terminals (labeled “IN_1” through “IN_4”) and output terminals (labeled “OUT_1” through “OUT_4”) are also shown to be included in the various test blocks 104 in FIG. 6. These represent interconnections of the test blocks to other parts of self-testing circuit 102 (e.g., to other test blocks 104, etc.) so that each test block can receive input signals and generate output signals in accordance with whatever function each test block may have. As such, it will be understood that each test block may include any suitable number of inputs and/or outputs according to its size, function, design, and so forth. In FIG. 6, however, it is noted that these input and output terminals are illustrated as being unconnected. This is not to indicate that each test block is isolated from the rest of the circuit during normal operation, as it will be understood that these input and output terminals would in fact generally be interconnected to other parts of the circuit. Rather, the inputs and output terminals are shown in FIG. 6 to be unconnected to emphasize that the testing described herein is generally not dependent or focused on the normal operating configurations of the test blocks or any stimulation that is being run through the test blocks in these configurations. Instead, the testing described herein is generally agnostic to how various test blocks 104 may be interconnected or what stimulus may run through their input and output terminals (though, in some examples, basic stimulus may be selected to ensure that one test block does not interfere with the testing of another or the like). Regardless of how the components 602 may be configured during normal operation, and regardless of how the test blocks 104 may be interconnected, the testing described herein is based on the configurations of the respective sets of components 602 (e.g., based on the test vector presently transmitted on test vector bus 106) and the current that is measured to be drawn from voltage rail 114, through the components 602 in their present configuration, to ground.

When a given test block 104 is enabled (i.e., when its respective enable input 604 is active such as by being driven high), the test vector on test vector bus 106 indicates what configuration of the set of components 602 is to be tested (e.g., how the components 602 are to be electrically connected or arranged for the test). For example, if test vector bus 106 is a four-bit bus, there would be up to 2\hat{ }4=16 different test vectors that could be transmitted on test vector bus 106. If it is desired for a test block to support more test configurations than can be represented by the test vector bus (e.g., more than 16 configurations for the example of a 4-bit bus), such as for a particularly complex test block that it is desirable to test in many configurations, additional enable inputs could be added to the test block to multiplex between different sets of test vectors. Thus, for example, a 4-bit test vector bus could transmit up to 16 different test vectors to a test block with one enable input, up to 32 different test vectors to a test block with two enable inputs, and so forth. As another example, a 6-bit test vector bus could transmit up to 64 different test vectors to a test block with one enable input, up to 128 different test vectors to a test block with two enable inputs, and so forth. In still other examples, dedicated (non-shared) electrical connections for communicating test vectors may be used instead of a test vector bus, as described above.

To decode the possible test vectors and convert them into an actionable reconfiguration of the set of components in the test block (e.g., a setting for a plurality of switches within the test block, as will be described in more detail below), FIG. 6 shows that each test block 104 may include a respective decoder 606 (e.g., decoder 606-1 in test block 104-1, decoder 606-2 in test block 104-2, etc.). The role of the decoder is to ensure that the set of components 602 for the test block are properly configured (e.g., electrically connected) in accordance with the test vector driven onto the test vector bus 106, at least when the enable input 604 for the test block is active.

Such reconfiguration may be performed in any suitable way. For instance, each test block 104 may include a set of switches strategically placed around the various components 602 within the test block in a manner that allows different electrical connections to be made between the components based on the state or setting of the switches. Based on a first test vector on test vector bus 106, a first setting may be determined (e.g., by a respective decoder 606, by test controller 110, etc.) for the set of switches within the test block, where the set of switches is configured to produce a first configuration for the set of components when the first setting is applied. Similarly, based on a second test vector on test vector bus 106, a second setting may be determined for the set of switches, where the set of switches is configured to produce a second configuration for the set of components when the second setting is applied. Additional configurations associated with additional test vectors may similarly be implemented by additional settings for the set of switches.

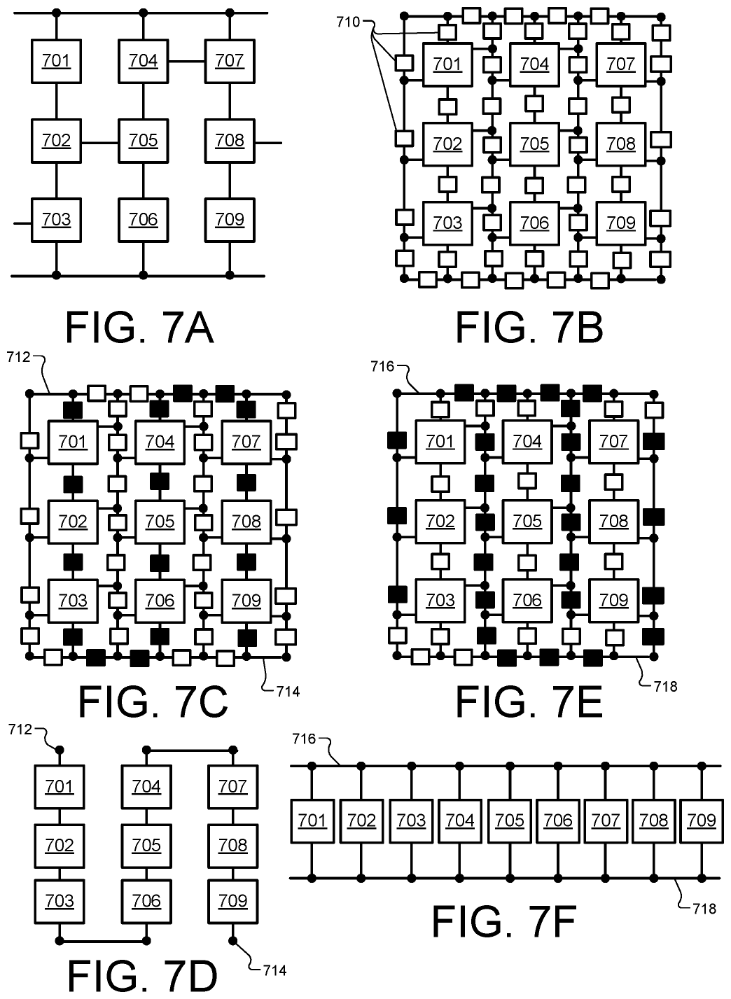

To illustrate, FIGS. 7A-7F show various aspects of how an illustrative set of switches within a test block may be configured with different settings to produce varied configurations for a set of components in the test block in accordance with principles described herein. Specifically, FIG. 7A shows boxes representing various example components 701, 702, 703, 704, 705, 706, 707, 708, and 709 that may be included in a particular test block. In FIG. 7A, a particular electrical configuration or wiring arrangement between the components is shown that may be understood to represent how these components will be connected during normal operation of the test block (e.g., after testing is complete and the self-testing circuit is being operated for its intended use).

FIG. 7B illustrates how a set of switches 710 could be added to the test block to allow for a large number of potential reconfigurations of components 701-709. Specifically, each switch 710 (only a few of which are explicitly labeled as such) is shown in FIG. 7B and other figures below as a small square that will be understood to be open or unconnected when it is not filled in (i.e., when the square is white, such as shown in FIG. 7B), and to be closed or connected when it is filled in (i.e., when the square is black). While FIG. 7B shows a relatively large number of switches to create a great flexibility and large number of ways that components 701-709 could be configured, it will be understood that the number and placement of switches in a set of switches for a test block may be designed in a more targeted way in certain implementations. For example, a small number of well-placed switches between a few components in a block may provide all the potential configurations desired for a given test plan, as will be further illustrated in an extended example below.

With the relatively large number of switches 710 added to this particular test block, FIGS. 7C-7F show very different test configurations that could be implemented by virtue of different settings for the set of switches (settings determined by a decoder such as described above). Specifically, FIG. 7C illustrates one setting for these switches 710 that causes components 701 through 709 to all be electrically connected in series with one another (e.g., to test that there is no disconnect or break in any of the components). A simplified diagram of the configuration created by the switch setting of FIG. 7C is shown in FIG. 7D. An input node 712 and an output node 714 are called out in both FIGS. 7C and 7D to show how the setting of the switches 710 in FIG. 7C may result in the equivalent configuration illustrated in FIG. 7D for this example.

In contrast, FIG. 7E illustrates another setting for the set of switches 710 that causes components 701 through 709 to all be electrically connected in parallel with one another (e.g., to test that there is no short in any of the components). A simplified diagram of the configuration created by the switch setting of FIG. 7E is shown in FIG. 7F. An input node 716 and an output node 718 are called out in both FIGS. 7E and 7F to show how the setting of the switches 710 in FIG. 7E may result in the equivalent configuration illustrated in FIG. 7F for this example.

The generic components represented by components 701-709 in FIGS. 7A-7F illustrate the general principle of how switches may be used to allow for electrical rearrangement and reconfiguration of a set of components within a test block. It will be understood, however, that real components may have differing functions, differing numbers of inputs and outputs, differing wirings, and other characteristics for which these principles may be adapted in any manner as may serve a particular implementation.

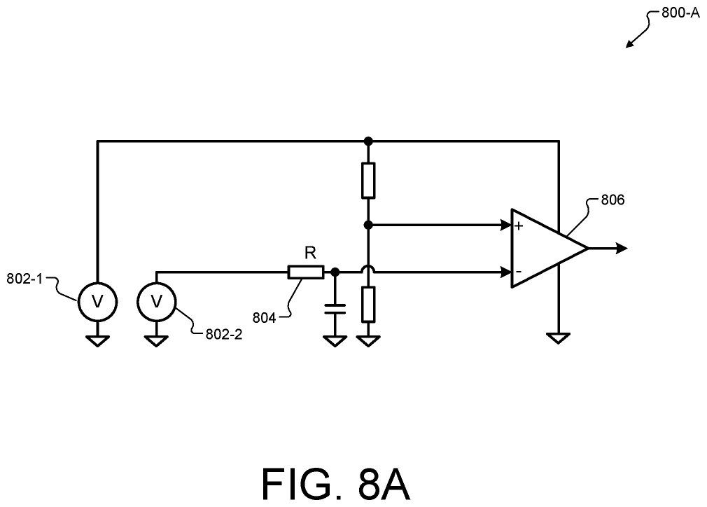

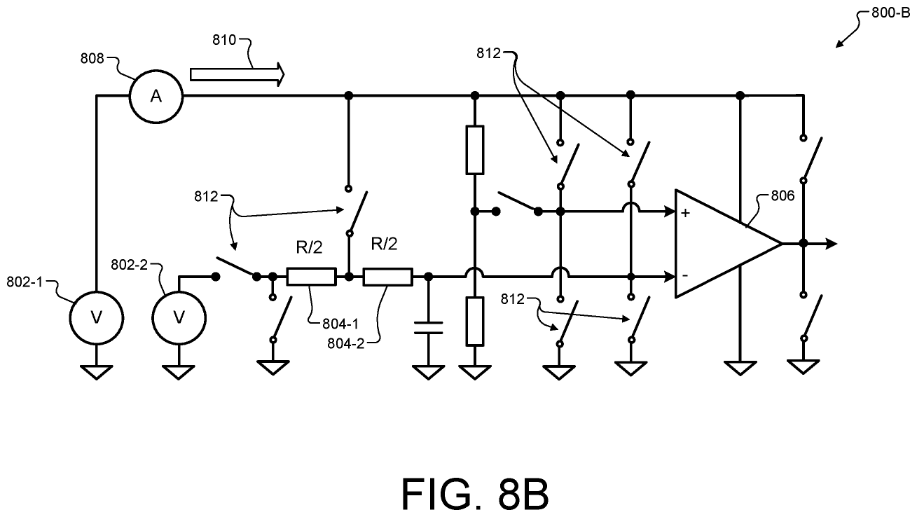

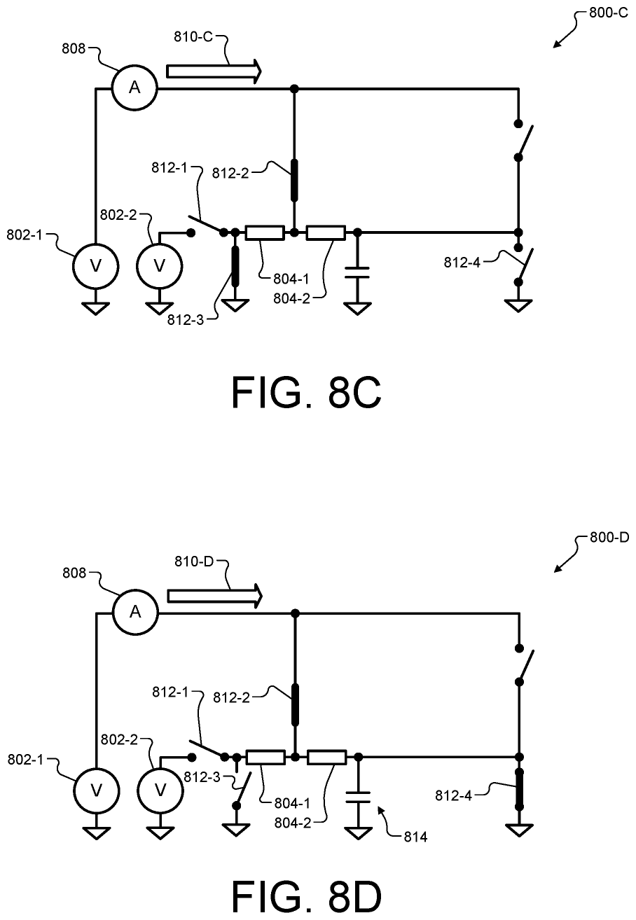

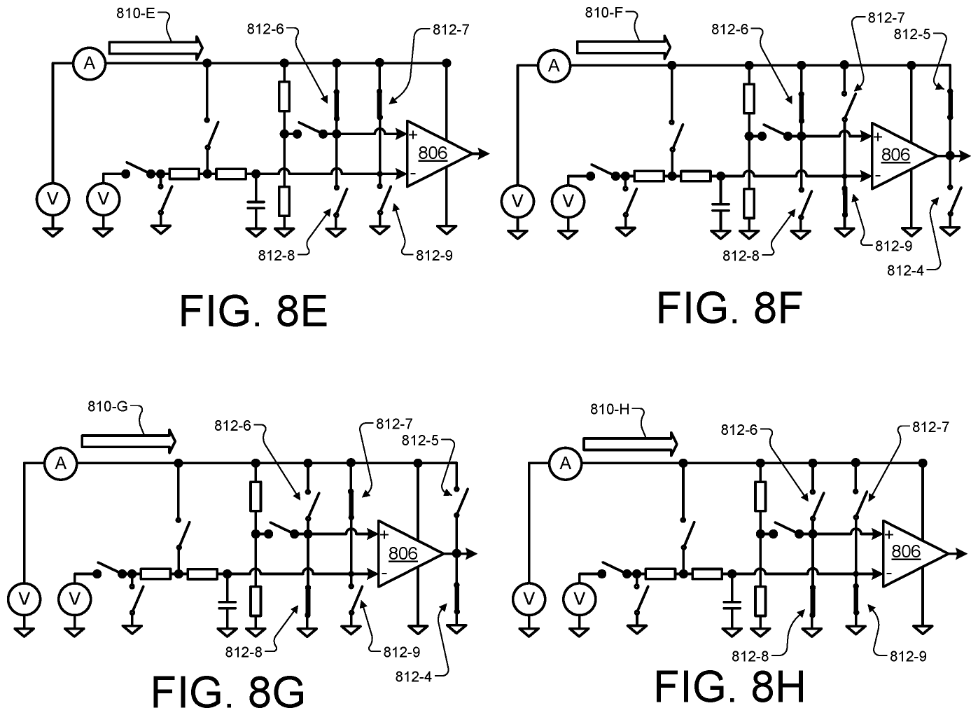

FIGS. 8A-8H show an extended example of a particular example test block and how it could be arranged into a variety of configurations to test various components included therein. As will be shown, the components of this relatively simple example may be arranged in varied configurations and tested using current-based built-in self-test in accordance with principles that have been described.

FIG. 8A is a circuit diagram 800-A that shows how this particular test block may be configured in operation. As shown, voltage sources 802-1 and 802-2 may provide power (voltage source 802-1) and/or a reference voltage (voltage source 802-2) for the components of the test block, which include a resistor 804 having a resistance value R, an operational amplifier 806, and other components not explicitly labeled (e.g., other resistors, a capacitor, etc.).

Rather than (or in addition to) testing the circuit in the operational configuration shown in circuit diagram 800-A, current-based built-in self-testing techniques described herein involve reconfiguring the components of the test block and measuring the current drawn for each configuration. To illustrate, FIG. 8B is a circuit diagram 800-B that shows how the test block may be implemented so as to be reconfigurable in ways that have been described and to be testable using current-based built-in self-testing principles. Specifically, as shown, circuit diagram 800-B splits resistor 804 into two resistors 804-1 and 804-2 that each have resistance value R/2, such that, together, the two resistors 804-1 and 804-2 still provide the same amount of resistance R as shown in circuit diagram 800-A. The voltage sources 802-1 and 802-2, as well as the operational amplifier 806 and the other resistors and capacitor, are still shown to be included in the circuit diagram 800-B. Additionally, circuit diagram 800-B shows the addition of a current monitor 808 that may be implemented by a current measurement circuit (e.g., current measurement circuit 108), a current 810 consumed by the test block and measured by current monitor 808, and a set of switches 812 (only some of which are explicitly labeled as such) in various locations to allow for the components to be set in different configurations as will be shown.

As a first example of how circuit-based built-in self-test may be used, FIGS. 8C and 8D show how resistor 804 may be tested. In this example, the set of components includes a resistor component (i.e., resistor 804) implemented as a first resistor (i.e., resistor 804-1) and a second resistor (i.e., resistor 804-2) that are configured to be in series during operation of the test block and to be on separate current paths for a first configuration and a second configuration of the test block. More particularly, as shown, various switches 812 are set (e.g., opened or closed) so as to create a configuration 800-C shown in FIG. 8C for measuring a first current 810-C drawn by the test block and associated with a first measured value for the first resistor 804-1. A different setting for these switches 812 is then applied to create a configuration 800-D shown in FIG. 8D for measuring a second current 810-D drawn by the test block and associated with a second measured value for the second resistor 804-2. More particularly, as shown, configuration 800-C is implemented by closing a switch 812-2 that is between the voltage node of voltage sources 802-1 (where first current 810-C is to be measured) and the node between the two resistors 804-1 and 804-2. A switch 812-1 is open to disconnect voltage source 802-2, thereby ensuring that all the current flow through resistor 804-1 will be measured by current monitor 808. A switch 812-3 is closed to connect the other side of resistor 804-1 to ground, thereby completing the current path of first current 810-C from voltage source 802-1, through current monitor 808 and resistor 804-1, to ground. At the same time, configuration 800-C also shows that a switch 812-4 is left open so that current is not also able to flow through resistor 804-2 during this test.

Complementing configuration 800-C, 800-D shows that switch 812-2 remains closed and switch 812-1 remains open to force current through the resistor component. However, whereas all of current 810-C was directed through resistor 804-1 in configuration 800-C, FIG. 8D shows that switch 812-3 may be set to open and switch 812-4 may be set to closed for configuration 800-D. In this way, a current 810-D will be measured that is driven by voltage source 802-1, through current monitor 808 and resistor 804-2, to ground. It is noted that if there were to be a short or other problem with a capacitor 814, current 810-C would be affected, and that a defect could thereby be detected. In other words, configuration 800-C may not only help test the resistor component (resistor 804), but may also help test capacitor 814.

Once currents 810-C and 810-D have been measured, a test controller such as test controller 110 may detect a defect in the test block based on a comparison indicating that the first measured value (for current 810-C) is different from the second measured value (for current 810-D) by more than a predetermined threshold. That is, since both resistors 804-1 and 804-2 are expected to have the same resistance value, and since configurations 800-C and 800-D are configured to direct and measure current flowing only through the two different resistors, any discrepancy between the first and second measured values may be indicative of a problem. For example, one resistor may have the wrong value, the capacitor 814 may be shorted, one of the resistors may be shorted, one of the resistors may be disconnected, or another problem may be present. While the current discrepancy above the predetermined threshold may not indicate which of these types of potential defects is present, it may indicate with a high degree of confidence that some defect is present that must be accounted for.

As another example of how circuit-based built-in self-test may be used, FIGS. 8E, 8F, 8G, and 8H show how a two-input component such as operational amplifier 806 may be tested. As shown, in this example, the set of components includes a two-input component (i.e., operational amplifier 806) that includes a first input (a non-inverting input in this example) and a second input (an inverting input in this example). In a series of different configurations shown in the different FIGS. 8E-8H, these inputs may be tied either to ground or to the supply voltage (the node of voltage source 802-1) in each possible combination.

Specifically, as shown in FIG. 8E, a first configuration corresponding to a first test vector may tie both the first input and the second input to the supply voltage. This is done by setting switches 812-6 and 812-7 to be closed while setting switches 812-8 and 812-9 to be open while a current 810-E is measured. It is noted that other switches such as switches 812-1, 812-2, and 812-3 (not explicitly labeled in FIGS. 8E-8H) are open so as to disallow current to flow through the portions of the circuit related to resistor 804 (those portions having been tested separately, as described above in relation to FIGS. 8C-8D).

As shown in FIG. 8F, a second configuration corresponding to a second test vector may tie the first input to the supply voltage and the second input to ground. This is done by setting switches 812-6 and 812-9 to be closed while setting switches 812-7 and 812-8 to be open while a current 810-F is measured. Again, other switches such as switches 812-1, 812-2, and 812-3 (not explicitly labeled in FIGS. 8E-8H) are open so as to disallow current to flow through the portions of the circuit related to resistor 804. The output of operational amplifier 806 is shown to be tied to the voltage supply in this example, however, by setting a switch 812-5 to be closed while switch 812-4 is open.

As shown in FIG. 8G, a third configuration corresponding to a third test vector may tie the first input to ground and the second input to the supply voltage. This is done by setting switches 812-7 and 812-8 to be closed while setting switches 812-6 and 812-9 to be open while a current 810-G is measured. Again, other switches such as switches 812-1, 812-2, and 812-3 (not explicitly labeled in FIGS. 8E-8H) are open so as to disallow current to flow through the portions of the circuit related to resistor 804. The output of operational amplifier 806 is shown to be tied to ground in this example, however, by setting switch 812-4 to be closed while switch 812-5 is open.

As shown in FIG. 8H, a fourth configuration corresponding to a fourth test vector may tie the first input and the second input to ground. This is done by setting switches 812-8 and 812-9 to be closed while setting switches 812-6 and 812-7 to be open while a current 810-H is measured. Again, other switches such as switches 812-1, 812-2, and 812-3 (not explicitly labeled in FIGS. 8E-8H) are open so as to disallow current to flow through the portions of the circuit related to resistor 804.

Once all of currents 810-E through 810-H have been measured and converted to respective current values, the detecting of the defect in the test block may be further performed based on one or more comparisons involving any or all of these currents in any combination as may serve a particular implementation. For example, certain values may be expected to be the same or to be related by a predetermined ratio that can be checked such that any discrepancy above a predetermined threshold may be indicative of a defect in the test block.

Various methods and processes described herein may be implemented at least in part as instructions embodied in a non-transitory computer-readable medium and executable by one or more computing devices. In general, a processor (e.g., a microprocessor) receives instructions, from a non-transitory computer-readable medium (e.g., a memory, etc.), and executes those instructions, thereby performing one or more operations such as the operations described herein. Such instructions may be stored and/or transmitted using any of a variety of known computer-readable media.

A computer-readable medium (also referred to as a processor-readable medium) includes any non-transitory medium that participates in providing data (e.g., instructions) that may be read by a processor. Such a medium may take many forms, including, but not limited to, non-volatile media, and/or volatile media.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. A method comprising:
transmitting, to a test block of a plurality of test blocks in a self-testing circuit, a first test vector corresponding to a first configuration for a set of components in the test block;
measuring a first current drawn by the test block when the set of components is in the first configuration;
transmitting, to the test block, a second test vector corresponding to a second configuration for the set of components, the second configuration being different from the first configuration;
measuring a second current drawn by the test block when the set of components is in the second configuration; and
detecting a defect in the test block based on a comparison between the first current and the second current.

2. The method of claim 1, further comprising:
determining, based on the first test vector, a first setting for a set of switches within the test block, the set of switches configured to produce the first configuration for the set of components when the first setting is applied; and
determining, based on the second test vector, a second setting for the set of switches, the set of switches configured to produce the second configuration for the set of components when the second setting is applied.

3. The method of claim 1, wherein the test block includes an enable input and is configured to:
when the enable input is active, allow the set of components in the test block to be put in a new configuration; and
when the enable input is inactive, disallow the set of components in the test block from being put in the new configuration.

4. The method of claim 1, further comprising:
transmitting, to an additional test block of the plurality of test blocks, a third test vector corresponding to a particular configuration for an additional set of components in the additional test block; and
measuring a third current drawn by the additional test block when the additional set of components is in the particular configuration;
wherein the detecting the defect in the test block is further based on a comparison between the first current and the third current.

5. The method of claim 1, further comprising:
transmitting the first test vector to an additional test block that is included in an additional self-testing circuit manufactured on a same wafer as the self-testing circuit and that corresponds to the test block; and
measuring a third current drawn by the additional test block when an additional set of components in the additional test block is in the first configuration;
wherein the detecting the defect in the test block is further based on a comparison between the first current and the third current.

6. The method of claim 1, further comprising:
converting, using an analog-to-digital converter circuit, the first current to a first value and the second current to a second value; and
storing the first value and the second value in a memory;
wherein the comparison between the first current and the second current is performed by comparing the first value and the second value as stored in the memory.

7. The method of claim 6, wherein:
the comparing the first value and the second value includes determining a ratio of the first value to the second value; and
the detecting the defect in the test block includes determining that the ratio falls outside a predetermined range.

8. The method of claim 6, wherein:
the comparing the first value and the second value includes determining a difference between the first value and the second value; and
the detecting the defect in the test block includes determining that the difference falls outside a predetermined range.

9. The method of claim 1, further comprising:
transmitting, to an additional test block of the plurality of test blocks, a third test vector corresponding to a particular configuration for an additional set of components in the additional test block;
measuring a third current drawn by the additional test block when the additional set of components is in the particular configuration; and
detecting a defect in the additional test block based on the third current without a comparison to another current.

10. The method of claim 9, wherein the detecting the defect in the additional test block includes determining that the third current indicates a short condition or a disconnect condition in the additional test block.

11. The method of claim 1, wherein:
the set of components includes a resistor component implemented as a first resistor and a second resistor that are configured to be in series during operation of the test block and to be on separate current paths for the first configuration and the second configuration;
the first current drawn by the test block is associated with a first measured value for the first resistor;
the second current drawn by the test block is associated with a second measured value for the second resistor; and
the detecting the defect in the test block is performed based on the comparison indicating that the first measured value is different from the second measured value by more than a predetermined threshold.

12. The method of claim 1, wherein:
the set of components includes a two-input component that includes a first input and a second input;
the first configuration ties the first input and the second input to a supply voltage;
the second configuration ties the first input to the supply voltage and the second input to ground;
a third configuration corresponding to a third test vector on the test vector bus ties the first input to ground and the second input to the supply voltage;
a fourth configuration corresponding to a fourth test vector on the test vector bus ties the first input and the second input to ground; and
the detecting the defect in the test block is further performed based on one or more comparisons involving a third current drawn by the test block when the set of components is in the third configuration and a fourth current drawn by the test block when the set of components is in the fourth configuration.

13. The method of claim 1, wherein the detecting the defect in the test block is performed by a test controller that is integrated into the self-testing circuit.

14. The method of claim 1, wherein the detecting the defect in the test block is performed by a test controller that is integrated into a testing device separate from the self-testing circuit.

15. A self-testing circuit comprising:
a plurality of test blocks including a test block configured to receive a first test vector and a second test vector, the first test vector corresponding to a first configuration for a set of components in the test block and the second test vector corresponding to a second configuration for the set of components;
a current measurement circuit configured to measure a first current drawn by the test block when the set of components is in the first configuration and to measure a second current drawn by the test block when the set of components is in the second configuration; and
a test controller electrically connected to the plurality of test blocks and the current measurement circuit, the test controller configured to transmit the first test vector and the second test vector to the test block and to detect a defect in the test block based on a comparison between the first current and the second current.

16. The self-testing circuit of claim 15, further comprising a set of switches within the test block, the set of switches configured to produce:
the first configuration for the set of components when a first setting for the set of switches is applied, the first setting determined based on the first test vector; and
the second configuration for the set of components when a second setting for the set of switches is applied, the second setting determined based on the second test vector.

17. The self-testing circuit of claim 15, further comprising an enable input for the test block, the test block configured to:
when the enable input is active, allow the set of components in the test block to be put in a new configuration; and
when the enable input is inactive, disallow the set of components in the test block from being put in the new configuration.

18. The self-testing circuit of claim 15, further comprising:
an analog-to-digital converter circuit configured to convert the first current to a first value and the second current to a second value; and
a memory configured to store the first value and the second value;
wherein the comparison between the first current and the second current is performed by comparing the first value and the second value as stored in the memory.

19. A non-transitory computer-readable medium storing instructions that, when executed, cause a test controller associated with a self-testing circuit to perform a process comprising:
transmitting, to a test block of a plurality of test blocks in the self-testing circuit, a first test vector corresponding to a first configuration for a set of components in the test block;
transmitting, to the test block, a second test vector corresponding to a second configuration for the set of components, the second configuration being different from the first configuration; and
detecting a defect in the test block based on a comparison between a first current and a second current, the first current being drawn by the test block when the set of components is in the first configuration, the second current being drawn by the test block when the set of components is in the second configuration.

20. The non-transitory computer-readable medium of claim 19, wherein the process further comprises:
determining, based on the first test vector, a first setting for a set of switches within the test block, the set of switches configured to produce the first configuration for the set of components when the first setting is applied; and
determining, based on the second test vector, a second setting for the set of switches, the set of switches configured to produce the second configuration for the set of components when the second setting is applied.
